(19) United States
(12) Patent Application Publication
(10) Pub. No.: US 2026/0351508 A1
(43) Pub. Date: Nov. 5, 2026

(54) MULTI-BEAM CHARGED PARTICLE MICROSCOPE FOR INSPECTION WITH REDUCED CHARGING EFFECTS

(71) Applicant: Carl Zeiss MultiSEM GmbH, Oberkochen (DE)

(72) Inventors: Tomasz GARBOWSKI, Neresheim (DE); Bjoern MIKSCH, Heidenheim an der Brenz (DE); Dirk ZEIDLER, Oberkochen (DE); Michel ALIMAN, Oberkochen (DE); Thomas DIETERLE, Murrhardt (DE); Stefan SCHUBERT, Oberkochen (DE)

(21) Appl. No.: 19/711,503

(22) Filed: Jun. 17, 2026

Related U.S. Application Data
(63) Continuation of application No. PCT/EP2024/025340, filed on Dec. 12, 2024.

(30) Foreign Application Priority Data
Dec. 19, 2023 (DE) 10 2023 212 967.1

(51) Int. Cl. H01J 37/147; H01J 37/20; H01J 37/28

(52) U.S. Cl. CPC H01J 37/1472; H01J 37/20; H01J 37/28

(57) ABSTRACT

A multi-beam charged particle system and a method of operating a multi-beam charged particle system which can provide a reduced impact of charging. A surface charge can be reduced by filtering individual beamlets of the plurality of primary beamlets, thereby limiting a scanning image acquisition with high resolution to a region of interest and reducing a charging of surface areas outside of the region of interest. A multi-beam charged particle beam system can comprise a filtering mechanism such as masking blades, a deflector array, or a multi-aperture lens array.

### CROSS-REFERENCE TO RELATED APPLICATIONS

The present application is a continuation of, and claims benefit under 35 USC 120 to, international application No. PCT/EP2024/025340, filed Dec. 12, 2024, which claims benefit under 35 USC 119 of German Application No. 10 2023 212 967.1, filed Dec. 19, 2023. The entire disclosure of each of these applications is incorporated by reference herein.

### FIELD

The disclosure relates to a multi-beam charged particle microscope with reduced charging of samples and a method of operating a multi-beam charged particle microscope for the inspection of semiconductor features with reduced charging.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam is transmitted through the openings of the multi-aperture plate, thereby providing in the beam path downstream of each opening an electron beamlets is formed whose cross section is defined by the cross section of the respective opening. The plurality of primary charged particle beamlets is focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated.

Generally, the imaging contrast of a multi-beam scanning electron microscope generally depends on the signal generated by secondary electrons, which generally depends on the secondary electron (SE) yield per primary electron and a geometrical collection efficiency of the electron microscope. The SE yield generally depends on material characteristics and the kinetic energy of the primary electrons. However, the SE yield can be influenced by charging effects of the sample surface. Charging effects can occur at local capacities or insulators, which can accumulate charges and can generate deteriorating electrical fields to the primary as well as secondary electron beamlets.

Different methods have been proposed to mitigate charging effects. Flood guns are widely used to pre-charge a sample surface. An example for a multi-beam charged particle beam system is given in U.S. Pat. No. 11,239,053. However, in some cases, application of this method has turned out to significantly disturb precision imaging. In International Patent application PCT/EP2023/025443, filed Nov. 24, 2023, a selected primary electron beam energy is used to operate at a point where secondary electron emission and incident primary electron current is in balance. Thereby, charging can be minimized. However, to minimize charging, different material compositions present at a surface of a wafer can involve different specific kinetic energies of primary electrons, and it is possible that the kinetic energy of primary beamlets cannot be adjusted individually during an image scan.

In a multi-beam scanning electron microscope, a relatively large exposure area on a wafer is exposed to irradiation with primary electrons. In certain inspection tasks, the charging behavior of a wafer sample has turned out to be different for individual primary charged particle beamlets, and individual beamlets suffer from deteriorating charging effects. For example, individual primary electron beamlets deflected or defocused due to a local charging. For example, individual secondary electron beamlets are deflected of defocused, leading to a reduced collection efficiency or crosstalk.

DE 10 2020 121 132 B3 discloses a charged particle beam system and a corresponding method with a mirror mode of operation.

DE 10 2020 125 534 B3 discloses a multiple particle beam microscope and an associated method providing a fast autofocus around an adjustable working distance.

US 2024/0297010 A1 discloses a writing apparatus for irradiating a predetermined position on an irradiation target with multiple charged beams to write a predetermined pattern on an irradiation target. The writing apparatus includes: a beam generation mechanism generating multiple charged particle beams; a blanking aperture mechanism comprising a limiting aperture substrate shielding the generated multiple charged particle beams and a deflector deflecting the multiple charged particle beams in a predetermined direction, and blanking the multiple charged particle beams; a stage having the irradiation target mounted thereon and being movable; a driver moving the limiting aperture substrate; and a controller controlling the writing apparatus. The controller moves the limiting aperture substrate from an arrangement location at the time of writing in a plane perpendicular to an axial direction of the multiple charged particle beams in a blanking period, and returns the limiting aperture substrate to the arrangement location at the time of writing.

### SUMMARY

There remains a desire to mitigate charging effects or avoidance of charging of samples during wafer inspection. The disclosure seeks to provide an improved multi-beam charged particle imaging system and an improved method of operation of a multi-beam charged particle beam system, which, for example, is configured to reduce charging effects during the inspection of semiconductor samples.

The disclosure provides a multi-beam charged particle imaging system and an improved method of operation of a multi-beam charged particle beam system is provided, by which surface charges generated during scanning image acquisition with a plurality of primary charged particle beamlets can be reduced or avoided. According to the disclosure, surface charges can be at least partially reduced, such that an image acquisition can be performed with higher accuracy and with at least a reduction of deteriorating effects of surface charges.

In a multi-beam scanning electron microscope, a relatively large exposure area on a wafer is typically exposed to irradiation with a plurality of primary electrons, where the number J of individual beamlets can reach large numbers of for example J>90, J>300, or J>1000. Thereby, a relatively large area of a sample such as a semiconductor mask or wafer is exposed, with a diameter of an area of for example approximately 100 micrometers (μm) or more, for example 300 μm. The relatively large exposure area may comprise areas which are of no interest during a wafer inspection task. Such areas of no interest can be intermediate ranges between dies, boundary areas of dies, or even boundary areas of a wafer sample. Generally, an inspection site can comprise large areas of no interest, for example areas comprising semiconducting or isolating sample material, which is sensitive to sample charging. According to embodiments, a multi-beam charged particle beam system comprises a mechanism for limiting the exposure at an inspection site to areas or regions of interest (ROI). Thereby, it can be possible to avoid a generation and accumulation of deteriorating surface charges.

A method of operating a multi-beam charged particle beam system according to an embodiment comprises an acquisition of an image of a surface segment of a wafer surface during the image scanning operation step A. The method further comprises a setting adjustment step S. Setting adjustment step S comprises adjusting the inspection site of a surface of a wafer in the object plane of the multi-beam charged particle beam system and selecting an image setting. The setting adjustment step S further comprises selecting a region of interest within an exposure area of the plurality of primary charged particle beamlets. The setting adjustment step S further comprises an adjusting mechanism for deselecting individual beamlets during image acquisition according to the selected region of interest.

A region of interest can be selected according to prior information. Prior information can be received or determined for example from CAD files of a wafer or previous inspection images, for example from optical inspection. Prior information can comprise registration information of a wafer, comprising the locations of the plurality of dies on the surface of the wafer.

In an example, the image scanning operation step A is limited to a scanning range according to a single die. Thereby, a charging at a border or edge of a die is reduced. In an example, the image scanning operation step A is limited to a scanning range at a border or edge of a wafer. Thereby, a charging at a border or edge of a wafer is reduced.

The method can further comprise an image acquisition step I for receiving and storing image data acquired during the image scanning operation step A.

According to an embodiment, a method of operating a multi-beam charged particle beam system with reduced surface charging comprises a filter step for blocking or filtering at least one beamlet selected from a plurality of primary charged particle beamlets according to regions on a surface of a wafer not required to be imaged during an inspection task.

In an example, the filter step comprises an adjustment of a masking blade, configured to block the at least one beamlet selected from the plurality of primary charged particle beamlets. In an example, the filter step comprises an actuation of a deflector array, configured for deflecting and guiding the at least one beamlet selected from the plurality of primary charged particle beamlets into a beam dump. In an example, the masking blades can be arranged near an intermediate image surface or close to the multi-aperture arrangement for generating the plurality of primary charged particle beamlets. In an example, deflector array is a part of the multi-aperture arrangement for generating the plurality of primary charged particle beamlets. In an example, the deflector array is arranged close to an intermediate image surface.

According to an embodiment, a method of wafer inspection comprises adjusting an inspection site of a surface of a wafer in an image plane of an object irradiation unit of a multi-beam charged particle beam system. The method can further comprise selecting at least one region of interest within an exposure area of the multi-beam charged particle beam system and adjusting an inspection setting. The adjustment of the inspection setting can include driving an adjustment mechanism for filtering at least one individual beamlet according to regions on a surface of a wafer outside of the at least one region of interest. The method can further comprise image scanning of the least one region of interest on the surface of the wafer. Driving the adjustment mechanism can include driving of at least one of a masking blade, a deflector array, and a multi-aperture lens array. Thereby, individual primary charge particle beamlets can be filtered, for example completely blocked, and an image scanning can be limited to the at least one region of interest. In an example, a beam energy of individual primary charge particle beamlets is reduced and a charging of regions outside the region of interest is reduced. In an example, the selection of the at least one region of interest is determined according at least one of a single die, a border or edge of a die, or a border or edge of a wafer. The selection of the at least one region of interest can be determined from CAD data of the wafer at the inspection site. Generally, the selection of the at least one region of interest is determined to reduce a surface charging outside the region of interest.

According to an embodiment, a multi-beam charged particle beam system comprises an emitter of primary charged particles and a multi-aperture arrangement for generating a plurality of primary charged particle beamlets. The multi-beam charged particle beam system can further comprise at least one of a masking blade or a deflector array and a beam dump, configured for blocking at least one beamlet selected from the plurality of primary charged particle beamlets. The multi-beam charged particle beam system can further comprise a control unit comprising a memory storing software instructions and an operation processor for executing the software instructions, when executed causing the multi-beam charged particle beam system to perform any of the method steps described above.

According to an embodiment, a multi-beam charged particle beam system comprises an object irradiation unit configured for forming during use a plurality of focus spots of a plurality of primary charged particle beamlets in an image plane and a sample stage, configured for holding a surface of a sample such as a lithography mask or a wafer in the image plane. The multi-beam charged particle beam system can further comprise a detection unit, configured for collecting and imaging a plurality of secondary electron beamlets, which are excited at the sample surface during exposure by the plurality of primary charge particle beamlets, onto an image detector, and a control unit. The object irradiation unit can comprise a charged-particle multi-beamlet generator configured for generating during use the plurality of primary charged particle beamlets, and a filtering mechanism for filtering at least one primary charged particle beamlet. The control unit can be configured to control the filtering mechanism to filter at least one primary charged particle beamlet selected from the plurality of primary charged particle beamlets according to a predetermined exposure area of the surface of the sample. In an example, the filtering mechanism is given by at least one movable masking blade. The at least one movable masking blade can be arranged in proximity of an intermediate image surface of the object irradiation unit. In an example, the filtering mechanism is given by a deflector array and a beam dump. Thereby, individual primary charged particle beamlets can be deflected into the beam-dump before reaching regions outside a region of interest. For example, the deflector array can be arranged in proximity of an intermediate image surface of the object irradiation unit. For example, the deflector array can be arranged within the charged-particle multi-beamlet generator of the object irradiation unit.

In an example, the filtering mechanism is given by a lens array and an aperture stop array configured to adjust a beam current (I1, I2, I3) of at least one primary charged particle beamlet. Thereby, a beam current can be reduced and charging outside of a region of interest can be reduced.

The disclosure is useful for wafer inspection. In an example, a task of a wafer inspection is the investigation of defects or dimensions of structured photoresist. Photoresist is an insulator and shows strong charging effects. With an apparatus and method according to embodiments, an effect of charging of structured photoresist can be minimized. In an example of a wafer inspection task, structures to be investigated are arranged at a border or edge of a die. For example, a dedicated process control monitor (PCM) can be arranged close to an edge of a die. With an apparatus and method according to embodiments, a charging of a gap surface between two dies or at an edge of a die can be avoided, and a deteriorating effect of a charging can be avoided.

### BRIEF DESCRIPTION OF THE DRAWINGS

Embodiments of the present disclosure will be explained in more detail with reference to drawings, in which:

FIG. 1 is a schematic sectional view of a multi-beam charged particle system according to an embodiment;

FIGS. 2A-2B illustrate an example of a scanning image acquisition of a surface segment of a wafer;

FIG. 3 illustrates an example of an imaging setting during an image scanning operation;

FIG. 4 illustrates a secondary electron and backscattered electron yield in dependence of landing energy LE or primary charged particles;

FIGS. 5A-5C illustrate an example of a scanning image acquisition of a surface segment of a wafer;

FIG. 6 illustrates an example of a multi-beam charged particle beam system according to an embodiment;

FIG. 7A-7C illustrate examples of a filter operation with masking blades array arranged close to an intermediate image surface;

FIG. 8 illustrates an example of a method according to an embodiment;

FIG. 9 illustrates an example of a method according to an embodiment;

FIG. 10 illustrates an example of a multi-beam charged particle beam system according to an embodiment;

FIG. 11 illustrates an example of a multi-beam charged particle beam system according to an embodiment;

FIG. 12 illustrates an example of a multi-beam charged particle beam system according to an embodiment; and

FIG. 13 illustrates an example of a method according to an embodiment.

### DETAILED DESCRIPTION

In the exemplary embodiments of the disclosure described below, components similar in function and structure are indicated as far as possible by similar or identical reference numerals. Some array elements, for example the plurality of primary charged particle beamlets, are identified by a reference number. Depending on the context, the same reference number may also identify a single element out of the array elements. Each primary charged particle beamlet (3.1, 3.2, 3.3) is one of the plurality of primary charged particle beamlets (3).

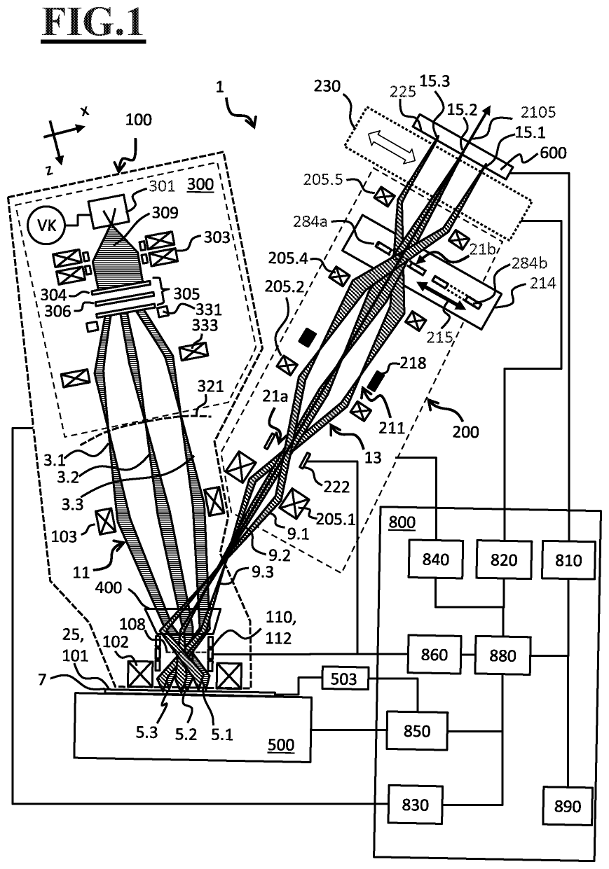

FIG. 1 is a schematic illustration of a multi-beam charged particle imaging system 1 (in short also multi-beam system 1) according to an embodiment. The multi-beam system 1 uses a plurality of charged particle beams for forming an image of an object 7. The multi-beam system 1 generates a plurality of J primary particle beams 3 which strike the object 7 to be examined in order to generate interaction products, e.g. secondary electrons, which emanate from the object 7 and are subsequently detected. The multi-beam system 1 is of the scanning electron microscope (SEM) type, which uses a plurality of primary electron beams 3 which are incident on a surface of the object 7 at a plurality of locations and generate there a plurality of primary electron beam focus spots 5, that are spatially separated from one another. The object 7 to be examined can be of any desired type, e.g., a semiconductor wafer or a semiconductor mask, and can comprise an arrangement of miniaturized elements. The surface 25 of the object 7 is arranged in an object plane 101 of an objective lens 102 of an object irradiation unit 100. The object 7 can be a wafer or a semiconductor mask.

A diameter of the minimal beam spots or focus spots 5 shaped in the object plane 101 can be small. Exemplary values of this diameter are below four nanometers, for example three nm or less. The focusing of the primary charged particle beamlets 3 for shaping the focus spots 5 is carried out by the objective lens system 102. In this case, the objective lens system 102 can comprise a magnetic immersion lens. Further examples of a focusing mechanism are described in the German patent DE 102020125534 B3, the entire content of which is herewith incorporated in the disclosure.

The plurality of focus spots 5 of the primary beamlets 3 form a regular raster arrangement of incidence locations, which are formed in the object plane 101. The number J of primary beamlets 3 may be five, twenty-five, or more. In practice, the number J of beamlets 3, and hence the number of incidence locations or focus spots 5, can be chosen to be significantly greater, such as, for example, J=10×10, J=20×30 or J=100×100. Exemplary values of the pitch P between the incidence locations are 1 micrometer, 10 micrometers, or more, for example 40 micrometers. For sake of simplicity, only three primary beamlets 3.1, 3.2 and 3.3 with corresponding focus points 5.1, 5.2 and 5.3 are shown in FIG. 1.

The primary particles 3 striking the object 7 generate interaction products, e.g. secondary electrons, back-scattered electrons, which emanate from the surface of the object 7. The interaction products emanating from the surface of the object 7 are shaped by the objective lens 102 to form secondary electron beamlets 9. For sake of simplicity, through the disclosure, all the interaction products are collectively described as secondary electrons, forming secondary electron beamlets 9.

The multi-beam system 1 provides a detection beam path 13 for guiding the plurality of secondary particle beamlets 9 to a secondary electron imaging system or detection unit 200. The secondary electron imaging system 200 comprises several electron-optical lenses 205.1 to 205.5 for directing the secondary particle beams 9 towards a spatially resolving particle detector 600. The detector 600 is arranged in the image plane 225. The detector 600 comprises a plurality of detection elements. Detection elements can for example be diodes such as PMDs, or CMOS detection elements, provided with electron-to-light conversion elements, or can be formed as direct electron detection elements.

In an example, the detector 600 comprises an electron-to-light conversion element, such as a scintillator plate, by which secondary electrons are converted into light, and a plurality of light detection elements. The combination of the electron-to-light conversion element and the plurality of light detection elements hereby form together a plurality of electron detection elements. The detector or image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is hereby incorporated by reference.

The imaging with the secondary electron imaging system 200 is strongly magnifying such that both the raster pitch of the primary beams on the wafer surface and the size and shape of focal points of the primary beamlets 3 are imaged in much magnified fashion. By way of example, a magnification is between 10× and 100× such that one nm on the wafer surface is imaged enlarged to between 10 nm and 100 nm. By way of example, a magnification is between 100× and 300× such that one nm on the wafer surface is imaged enlarged to between 100 nm and 300 nm. In an example, an image field of a multi-beam system with for example 100 μm diameter is enlarged to approximately 30 mm.

The primary particle beams 3 are generated in a beam generation apparatus 300 comprising at least one charged particle emitter 301, at least one collimation lens 303, a multi-aperture arrangement 305 and a first field lens 331 and a second field lens 333. The charged particle emitter 301 is connected to a voltage supply for providing an emitter voltage VK to the emitter 301 and generates at least one diverging charged particle beam 309, which is at least substantially collimated by the at least one collimation lens 303, and which illuminates the multi-aperture arrangement 305. The multi-aperture arrangement 305 comprises at least one first multi-aperture or filter plate 304, which has a plurality of J openings formed therein in a first raster arrangement. Particles of the illuminating particle beam 309 pass through the J apertures or openings of the first multi-aperture plate 304 and form the plurality J of primary beamlets 3. Particles of the illuminating beam 309 which strike the first aperture plate 304 are absorbed by the latter and do not contribute to the formation of the primary beamlets 3. A multi-aperture arrangement 305 usually has at least a further multi-aperture plate 306, for example a lens array, a stigmator array or an array of deflection elements. In this example, the particle beam 309 is perfectly collimated by collimation lens 303. However, it is also possible to design the multi-aperture arrangement 305 for a diverging or converging incident particle beam 309.

Together with the field lens 331 and a second field lens 333, the multi-aperture arrangement 305 focuses each of the primary beamlets 3 in such a way that focal points are formed in an intermediate image surface 321. Alternatively, the beam foci and the intermediate image surface 321 can be virtual. The intermediate image surface 321 can be curved and tilted to pre-compensate a field curvature and image plane tilt of the charged particle imaging system arranged downstream of the intermediate image surface 321.

The at least one field lens 103 and the objective lens 102 provide a first imaging particle optical unit for imaging the surface 321, in which the beam foci are formed, onto the object plane 101 such that a second raster configuration of focus spots 5 of the primary beamlets is formed there. Typically, the surface 25 of the object 7 is arranged in the object plane 101, and the focal points 5 are correspondingly formed on the object surface 25. The plurality of primary beamlets 3 form a crossover point 108, in the vicinity of which a first scanning deflector 110 is arranged. The first scanning deflector 110 is used to deflect the plurality of primary beamlets 3 collectively and synchronously such that the plurality of focus spots 5 are moved simultaneously over the surface 25 of the object 7. The first scanning deflector 110 is driven by a scanning control unit 860 such that in an inspection mode of operation, a plurality of two-dimensional image data of the surface is acquired. Additionally, the multi-beam system 1 can comprise further static deflectors and multipole elements 112 configured to adjust the position and beam shapes of the plurality of the primary beamlets 3.

The objective lens 102 and the projection lenses 205 provide a secondary electron imaging system 200 for imaging the object plane 101 onto the detection plane 225. The objective lens 102 is thus a lens or a lens system that is part of both the first and the second particle optical unit, while the field lenses 103, 331 and 333 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary electron beamlets 9 transmit during use the first deflection scanner 110 in opposite direction and the scanning movement of the secondary beamlets 9 is partially compensated. The secondary electrons have typically a different kinetic energy compared to the primary electrons. Therefore, the scanning movement of the moving irradiation positions is only partially compensated. The secondary electron imaging system 200 therefore comprises the second, collective beam deflector 222 which is arranged in the vicinity of a crossover plane or pupil plane 21a of the secondary electron beamlets 9. The second, collective beam deflector 222 is operated synchronously with the first beam deflector 110 and compensates during use a beam deflection of the secondary electron beamlets 9 such that the focus points 15 of the secondary beamlets 9 remain at constant position on the detection plane 225. Thereby, each focus points 15 of each individual secondary beamlet 9 is kept within the area of a set of detection elements, which is assigned to the individual secondary beamlet 9.

Together with the objective lens 102, the lenses 205 serve to focus the secondary beams 9 on the spatially resolving detector 600 and, in the process, compensate the imaging scale and the twist of the plurality of secondary electron beamlets 9 as a result of a magnetic lens such that a third raster arrangement of the focal points 15 of the plurality of secondary electron beamlets 9 remains constant on the detector plane 225. The electron-optical lenses 205.1 to 205.5 are shown as magneto-optical elements but are not limited to magneto-optical elements and can comprise also electro-static lens elements or stigmators. The secondary electron imaging system 200 further comprises an exchangeable contrast aperture 284a, 284b, mounted on an aperture filter module 214 at a pupil plane 21 of the secondary electron imaging system 200. With an exchange mechanism (not shown), different aperture stops 284a or 284b can be positioned in the second pupil plane 21b and aligned with respect to the optical axis 2105 of the secondary electron imaging system 200.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multi-beam charged particle imaging system 1 furthermore comprises a control unit 800 configured both for controlling the individual particle optical components of the multiple particle beam system and for evaluating and analyzing the signals obtained by the detector 600. In this case, the control or controller unit 800 can be constructed from a plurality of individual electronic computers or electronic components. By way of example, the control unit 800 comprises a control operation processor 880, a control module 840 for the control of the electron-optical elements of the secondary electron imaging system 200 and a control module 830 for the control of the electron-optical elements of the primary beamlet generation unit 100. The control unit 800 further comprises a stage control module 850 for positioning the sample surface 25 or sample 7 by stage 500 within the object plane 101. The control unit 800 further comprises a control module to adjust a sample voltage VS, which is connected to a module 503 for supplying the sample voltage VS to the sample 7, said sample voltage VS also being referred to as extraction voltage. Thereby, during use, an extraction field is generated between the objective 102 and the surface 25 of the object 7. During use, the extraction field decelerates the primary charged particles of the primary beamlets 3 before the sample surface 25 is reached and generates an additional focusing effect on the plurality of primary beamlets 3. At the same time, the extraction field serves during use to accelerate the secondary particles out of the surface 25 of the object 7.

Further, the control unit 800 comprises the scanning control module 860. During an inspection mode of operation, a plurality of focus points 15 of secondary electron beamlets is formed in the detection plane 225, and a plurality of signals is recorded during scanning operation of the primary beamlets 3 over the surface 25 of the sample 7. The detector 600 comprises a plurality of sets of detection elements with one set of detection elements for each secondary electron beamlet 9. During use, each set of detection elements is configured to record the intensity signal of the assigned secondary electron beamlet 9. The plurality of intensity signals for the plurality of secondary electron beamlets 9 is transferred to the image data acquisition unit 810, where the image data is processed and stored in memory 890. The setup of the secondary electron optical imaging system 200, the detector 600, and the assignment of the sets of detection elements to the focus spots 15 of the secondary electron beamlets 9 is initially determined and stored in the memory 890 of the control unit 800 of the multi-beam charged particle imaging system 1.

According to the example of FIG. 1, the multi-beam charged particle imaging system 1 further comprises a retractable monitoring system 230, which can be inserted into the secondary electron beam path in front of the detection plane 225. The monitoring system 230 comprises further imaging elements and a high-resolution detector. The monitoring system 230 is connected to a monitoring control unit 820.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scanning operation step, the control unit 800 is configured to trigger the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

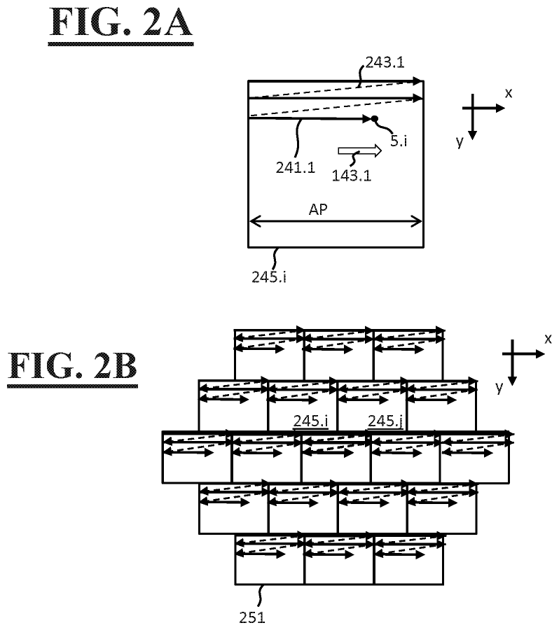

FIG. 2 illustrates a scanning operation of the plurality of primary charged particle beamlets 3 during an image acquisition. The scanning operation control module 860 is configured to provide during use a scanning signal to scanning deflector 110. Thereby, each primary charged particle beamlet 3 is deflected by the collective multi-beam raster scanner 110 such that the corresponding focus spot 5.i is scanned over an image patch 245.i of a single beamlet (FIG. 2A). Each image patch 245.i has a diameter AP of for example 8 μm to 10 μm. The scanning operation comprises a scanning of a plurality of parallel image scanning lines 241 along scanning direction 143.1 for image acquisition. At the end of each image scanning line 241, each beamlet 3 is moved back to the starting position of a next scanning line, which is also called “flyback” 243. During image acquisition along image scanning lines 241, the scanning operation is controlled to achieve a dwell time of about 50 ns at each image point, with for example 8000 images points per image scanning line 241. The time for flyback 243 can be much shorter, for example 20 ns in total. FIG. 2B shows the parallel operation of a plurality of primary charged particle beamlets 3 to acquire an image of a surface area segment 251 of a wafer surface, consisting of a plurality of image patches 245.

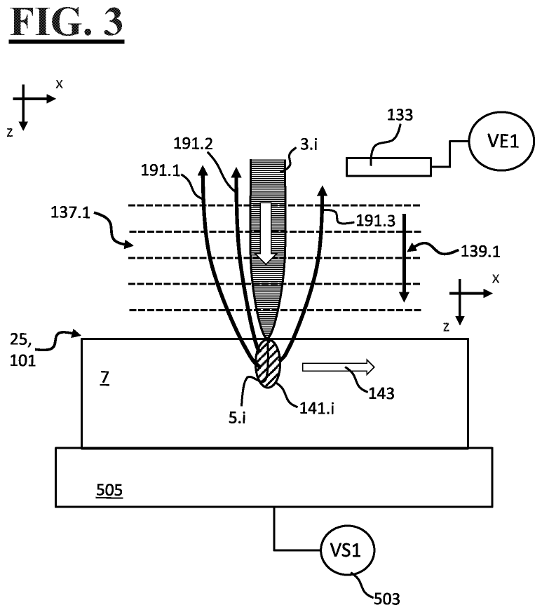

The image formation and extraction mechanism is further illustrated in FIG. 3. A primary charged particle beamlet 3.i is focused during an image scanning operation step to focus point 5.i and impinges on the surface 25 of wafer 7 and forms an interaction volume 141.i within the wafer 7. For example, during the operation at the low energy levels below 1 keV, the interaction volume 141.i has a small extension below 5 nm. During use, a parallel extraction field 137 is generated, with electrical field vectors 139 being perpendicular to the wafer surface 25. The extraction field 137 (illustrated by equipotential lines) extracts and accelerates secondary electrons generated in the interaction volume 141.i along electron trajectories (some example of electron trajectories 191.1 to 191.3 are shown) in opposite propagation direction to the primary electron beam direction. After collecting sufficient secondary electrons during the dwell time of about 50 ns, the primary beamlet 3.i is moved by scanning deflector (not shown) along scanning direction 143 to the next image pixel position. Thereby, image data of a surface of a sample is acquired.

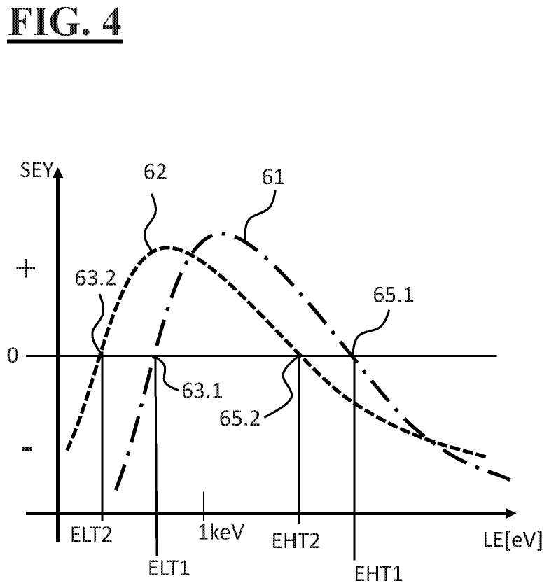

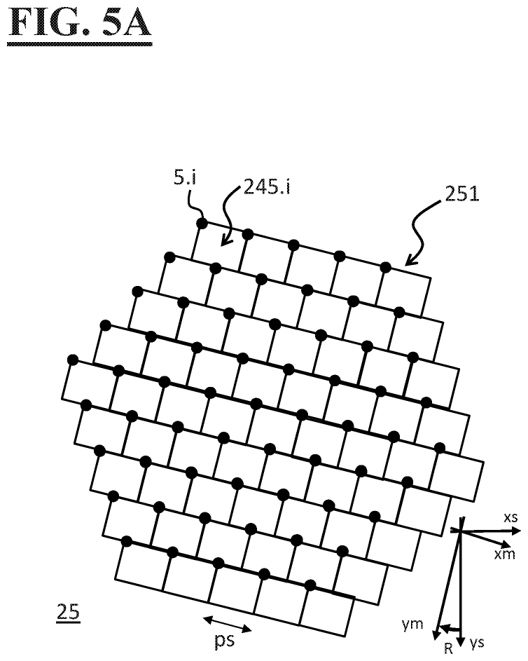

The backscattered and secondary electron yield SEY is a function of the primary beam energy. FIG. 4 illustrates two examples of residual charging curves for different material compositions in dependence on the primary charged particle energy. The residual charging of a first material composition with is illustrated with reference number 61. The residual charging curve 61 show areas in which a sample is positively charged between the two kinetic energies ELT1 and EHT1, i.e. more secondary and backscattered electrons leave the sample compared to the deposited charge by the primary electrons. The residual charging curve 61 show areas where a sample is negatively charged at energies below ELT1 and above EHT1, i.e. less secondary or backscattered electrons leave the sample compared to the deposited charge, leading to a negative charge accumulation in the sample. The residual charge of a second material composition is illustrated with reference number 62, with the two kinetic energies ELT2 and EHT2. At the transition energies ELT and EHT, for each material composition, respectively, a sample charging is minimized. A first minimum sample charging is achieved at a low kinetic energy ELT, corresponding to the low energy transition point ELT with no sample charging. A low energy transition point ELT is depending on the material composition and is about below 800 eV, below 500 eV or even less. For example, for typical materials such as Cu, W, Al, Si, SiO2 or SiN2, comprised in semiconductor wafers, the low energy transition point is between 80 eV and 250 eV. A second minimum sample charging is achieved at a higher kinetic energy EHT, corresponding to the high energy transition point EHT with no sample charging. The high energy transition point EHT is depending on the material composition and is typically above 1 keV. For example, the high energy transition point EHT of copper (Cu) or tungsten (W) is above 2 keV, where an imaging with high resolution is not possible anymore. A low kinetic energy transition point ELT is sometimes also called the instable neutral point 63. A high kinetic energy transition point EHT is sometimes also called the stable neutral point 65. The backscattered and secondary electron yield SEY and the transition points ELT and EHT are however further depending on topographic effects. By proper adjustment of the extraction field generated by voltage supply 503, a residual charging of a selected material composition can be minimized.

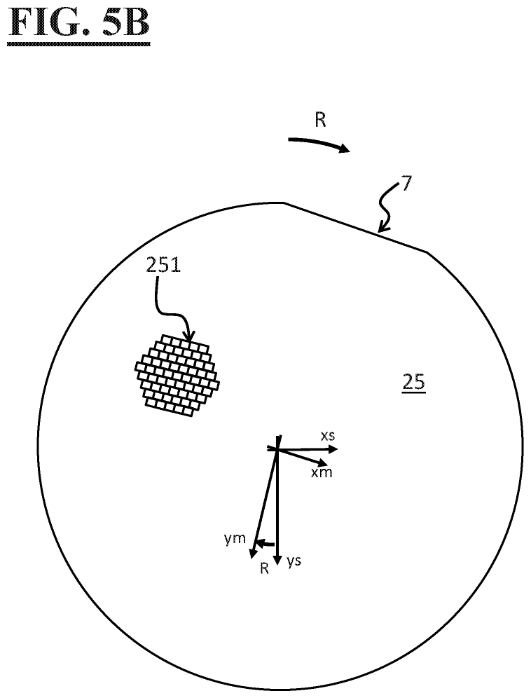

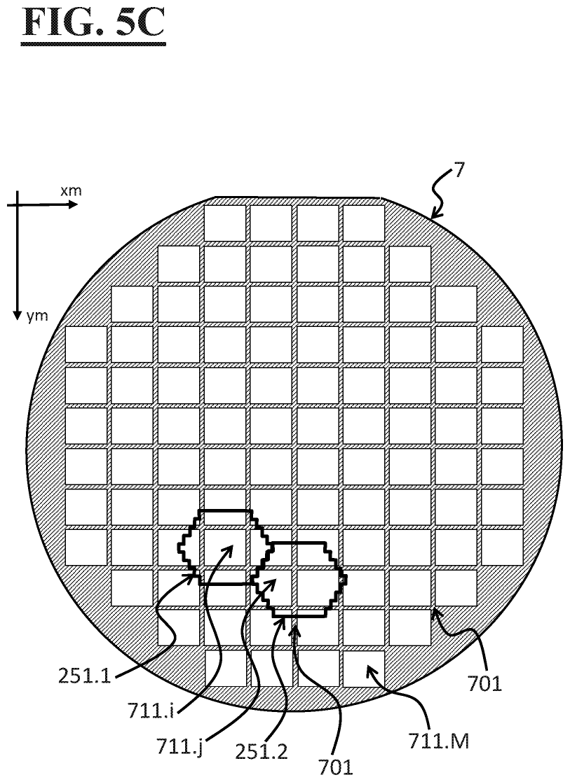

FIG. 5A illustrates an example of a surface area 251 which is captured by the plurality of primary charged particle beamlets 3. A plurality of focus points 5 is illustrated at each starting point of an image subfield or patch 245 corresponding to a single primary beamlet. The focus points 5 are formed on the surface 25 according to a selected imaging setting, comprising an adjustment of a pitch ps of for example 8 μm or 10 μm. As a consequence, the raster of focus points can be rotated by angle R with respect to a coordinate system (xs, ys) of the image plane 101. FIG. 5B illustrates the surface area 251 on a surface 25 of a wafer 7. To compensate the rotation by angle R, the wafer 87 is rotated by the stage 500 by angle R, thereby the image subfield or patch 245 are aligned with the rows and columns of dies formed on the surface of the wafer 7. FIG. 5C illustrates two adjacent surface area 251.1 and 251.2 of two consecutive image acquisitions. Thereby, a composite image of a plurality of dies 711.i, 711.j to 711.M of a wafer 7 are acquired. According to prior art, the adjacent surface areas 251.1 and 251.2 comprise image regions of boundaries of dies or gaps between dies 701, which are typically not the regions of interest. Those boundaries of dies or gaps between dies 701, however, are typically comprising semiconducting or isolating material, which accumulates surface charges during image acquisition. Generally, in some examples, charging effects appear at specific structures or features at limited areas of a surface 25 of a wafer 7. Charging effects typically accumulate at those limited areas. In some example, these limited areas are not within the region of interest of an inspection task and can therefore be excluded from an image acquisition.

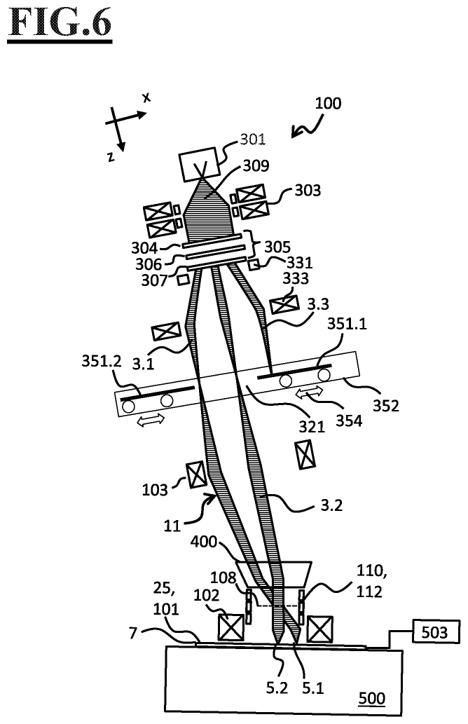

According to an example, an improved multi-beam charged particle beam system 1 therefore comprises a mechanism to avoid exposure of boundaries of dies or gaps between dies 701, and thereby minimizes deteriorating surface charges. An example of a multi-beam charged particle beam system 1 is illustrated in FIG. 6. The illustration is limited to the object irradiation unit 100, and reference is also made to the description of FIG. 1. The object irradiation unit 100 comprises a masking blade unit 352 with a plurality of masking blades 351.1, 351.2, which are mounted on masking blade driving devices 354 for positioning masking blades 351.1, 351.2. In an example, the masking blades 351.1, 351.2 are arranged in or close to the intermediate image surface 321. Masking blades 351.1, 351.2 can be adjusted with masking blade driving devices 354 within the intermediate image surface 321 and at least one or more of the primary beamlets 3 can be blocked from reaching the sample surface 25. In the example illustrated in FIG. 6, beamlet 3.3 is blocked by masking blade 351.1. The masking blade driving devices 354 typically comprise a bearing or guide for precision movement of the masking blades 351.1 or 351.2, and an actuator, for example a piezo actuator, a voice coil or other types of movement mechanisms.

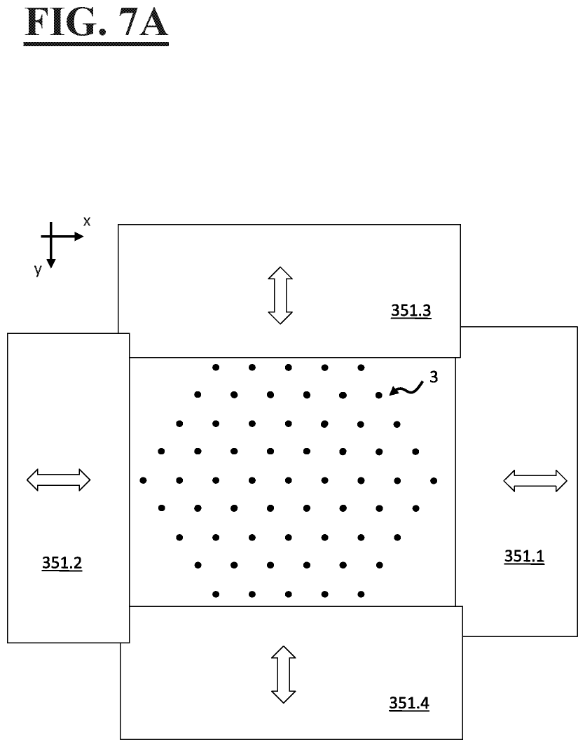

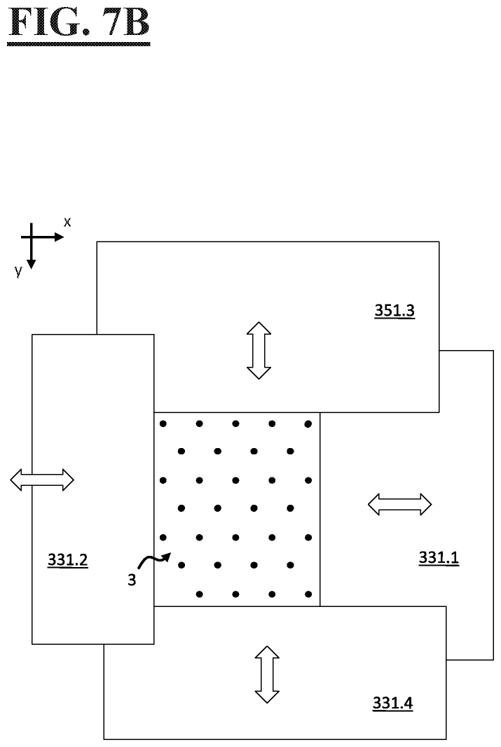

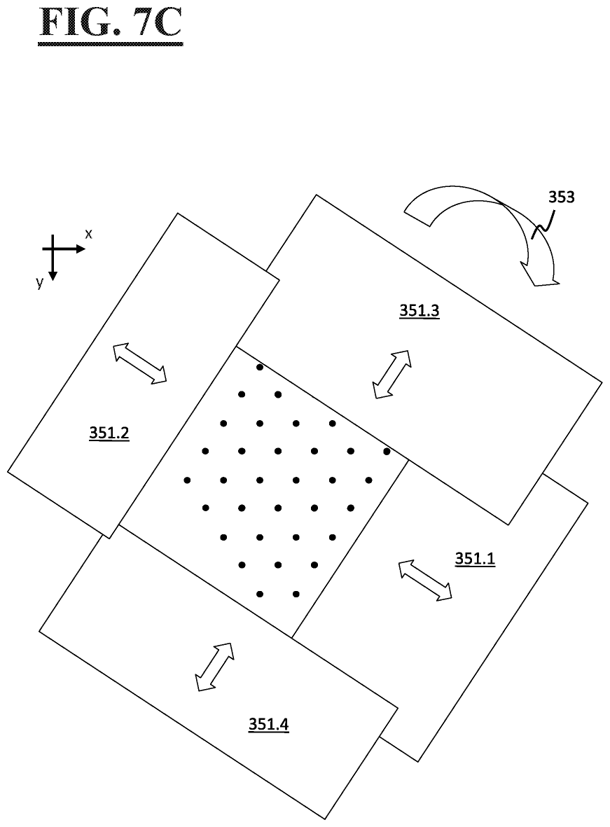

FIGS. 7A-7C illustrate four masking blades 351.1 to 351.4 in a cross section with the plurality of primary charged particle beamlets 3 in a hexagonal arrangement. The masking blades 351.1 to 351.4 are arranged horizontally and vertically according to the borders or gaps 701 between dies of a wafer. FIG. 7A illustrates the masking blades 351.1 to 351.4 in open position without blocking any primary beamlet 3. FIG. 7B illustrates an example, where masking blades 351.1 and 351.3 are moved by masking blade driving device 354 in order to block some of the primary charged particle beamlets 3 according to a border 701 of a die. FIG. 7C illustrates a further example, where the four masking blades 351.1 to 351.4 are rotated by rotation vector 353 in order to compensate a rotation of the plurality of primary charged particle beamlets 3 by objective lens 102. In this example, masking blade driving device 354 comprises a rotation actuator for rotating the masking blades 351.1 to 351.4 according to a rotation of the plurality of primary charged particle beamlets 3 by objective lens 102.

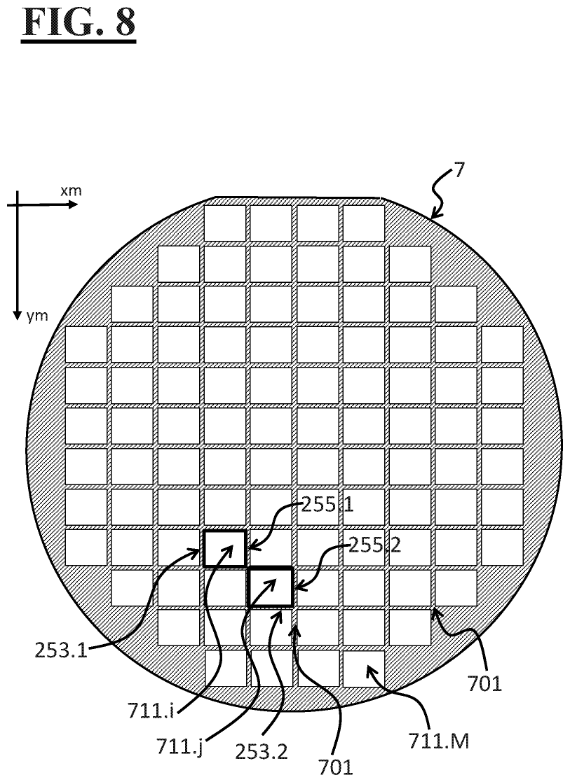

FIG. 8 illustrates an example of an image acquisition with a plurality of primary beamlets 3, limited to a region of interest 253.1, 253.2. In this example, the image acquisition is limited by actuation of the masking blades 351.1 to 351.4 to a single die 711 on a wafer, and gaps 701 between the dies 711.i, 711.j are excluded from the scanning image acquisition by blocking the corresponding primary beamlets 3 with masking blades 351.1 to 351.4. In this example, the dies 711.i, 711.j are corresponding to the regions of interest 255.1 and 255.2.

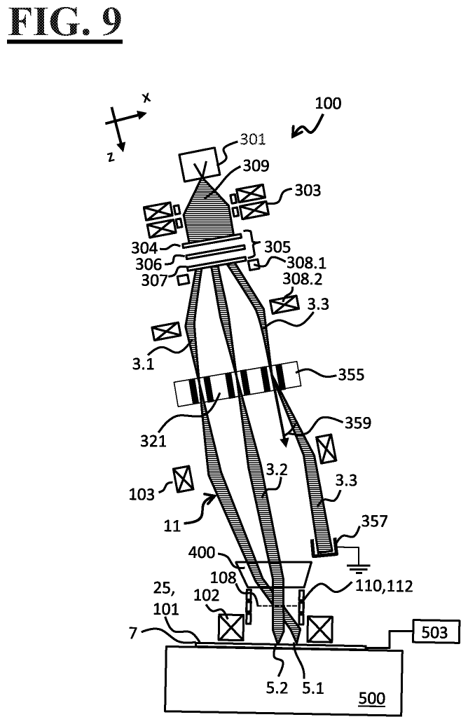

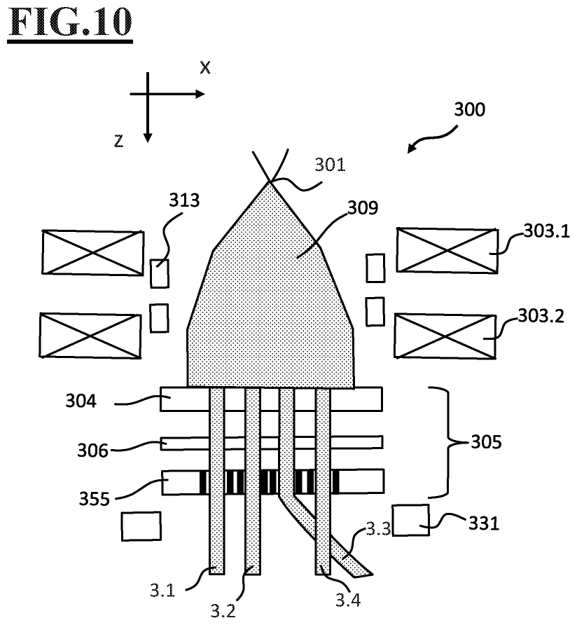

FIG. 9 illustrates another example of an object irradiation unit 100. Same reference numbers are used as in FIGS. 1 and 6, and reference is also made to the description of FIGS. 1 and 6. Instead of masking blades 351, a deflector array 355 is arranged in vicinity of the intermediate image surface 321 for individually deflecting primary charged particle beamlets 3. In the example illustrated in FIG. 9, primary beamlet 3.3 is deflected by deflector array 355 by deflection angle 359, such that primary beamlet 3.3 is propagating and guided into a beam dump 357. Primary beamlet 3.3 does not reach the surface 25 of the sample 7 and does not contribute to imaging or charging of a gap 701 between adjacent dies. The blocking of a primary charged particle beamlet 3 by deflector array 355 is not limited to beamlets at the periphery of the plurality of primary charged particle beamlets 3. FIG. 10 illustrates another example. Here, the deflector array 355 is part of the multi-aperture arrangement 305 and is configured to individually deflect a primary charged particle beamlet 3, in FIG. 10 illustrated at the example of beamlet 3.3, such that beamlet 3.3 is guided to a beam dump (not shown in FIG. 10) and does not contribute to the imaging and charging of the wafer sample 7.

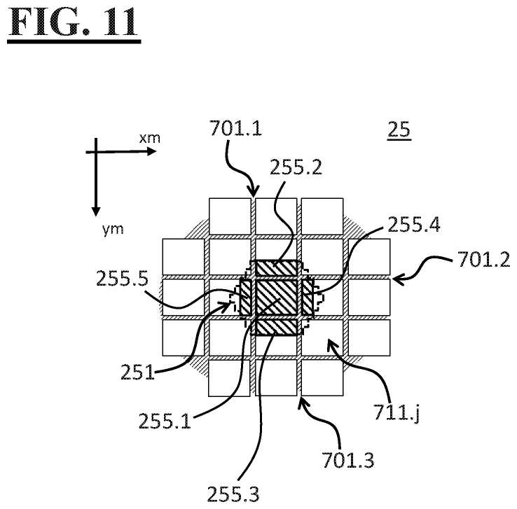

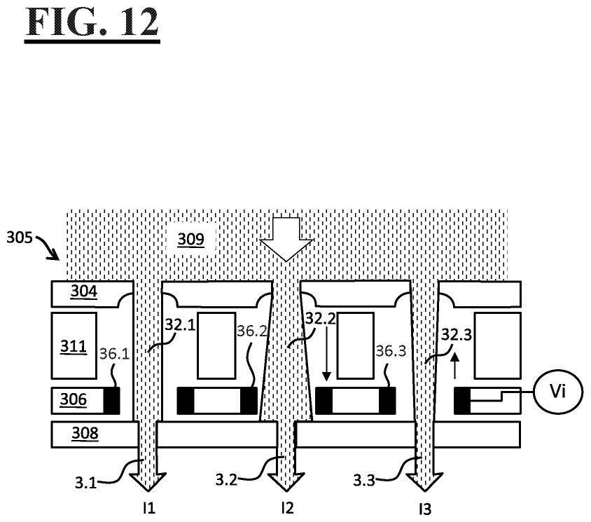

FIG. 11 illustrates an example of an application of an individual blocking of primary charged particle beamlets 3 at positions corresponding to gaps 701.1, 701.2, 701.3 between dies 711. Thereby, an exposure of a surface 25 of a wafer 7 is limited to disjunct regions of interest 255.1, 255.2, 255.3, 255.4 and 255.5. In the example, the blocking or filtering of beamlets 3 is further assisted by masking blades 351, thereby the regions of interest 255.4 and 255.5 are limited to rectangular shape.

A charging of regions outside a region of interest 255 is avoided by filtering or blocking individual primary beamlets 3. A filtering or blocking can be achieved by positioning the masking blades 351. Thereby, primary beamlets 3 are blocked during an image acquisition. A filtering or blocking can be achieved by deflecting individual primary beamlets 3 with for example an electrostatic deflector 355. With a deflector 355, it is possible to block or filter an individual primary beamlet during image acquisition, thereby allowing an even more flexible limitation of an image acquisition to a region of interest 255.

In some examples, it is however not necessary to completely block an exposure of regions outside a region of interest 255. In an example, a deteriorating surface charging is avoided or minimized by reducing the beam current of an individual beamlet 3. An example is illustrated in FIG. 12. The example of FIG. 12 is also disclosed in PCT/EP2023/025443, filed on Oct. 24, 2023, which is hereby incorporated by reference. FIG. 12 illustrates a multi-aperture arrangement 305, comprising a first filter plate 309 for generating a plurality of pre-filtered beamlets 32.1, 32.2 and 32.3. Multi-aperture arrangement 305 further comprises a current-limiting filter plate 308 for generating the plurality of primary beamlets 3.1 to 3.3 (for simplicity, only three beamlets are shown). Multi-aperture arrangement 305 further comprises a spacer 311 and a multi-aperture lens array 306, which is configured to either pass, focus or defocus each primary beamlet individually. Thereby, a beam diameter of each pre-shaped beamlet 32.1 to 32.3 is modified and a current I1 to 3 of each beamlet 3.1 to 3.3 generated by passing apertures of current-limiting filter plate 308 is individually adjusted. Thereby, a first current I3 of a first beamlet 3.3 exposing a region of interest 255 can be increased, while a second current I2 of a beamlet 3.2 can be reduced and a charging of a region outside a region of interest 255, for example a border or gap 701, can be reduced. Thereby, for example, image information of lower resolution can be obtained from regions outside the regions of interest 255.

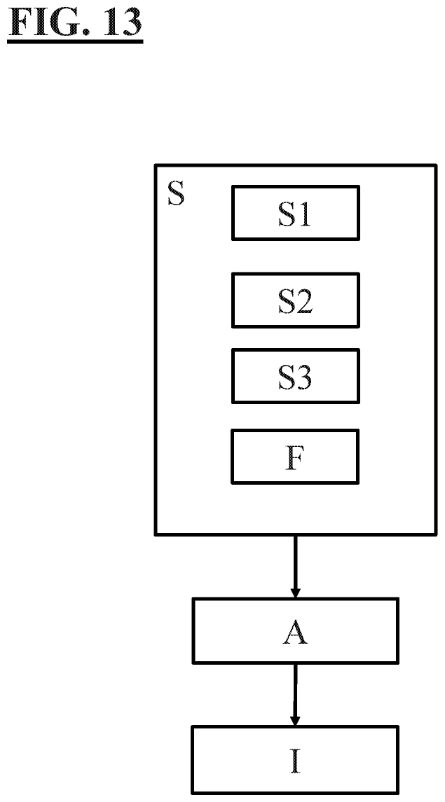

According to an embodiment, a method of operating a multi-beam charged particle beam system 1 is provided. An example of the method is illustrated in FIG. 13. The method comprises a setting adjustment step S. Setting adjustment step S comprises a first step S1 of selecting an inspection site on a surface 25 of a wafer 7 in the object plane 101 of the multi-beam charged particle beam system 1. First step S1 further comprises selecting an image setting. For example, a magnification or pitch ps of the focus points 5 of the primary beamlets 3 and landing energy LE of primary electrons is selected. For example, a landing energy LE is selected to achieve a large secondary electron yield SEY for an insulating material composition such as silicon dioxide of high-k dielectrics, where charges are accumulated. Optionally, prior information about the material composition of the surface 25 of the wafer 7 at the inspection position is loaded for example from a CAD file. A second step S2 comprises adjusting the inspection site of a surface 25 of a wafer 7 in the object plane 101 of the multi-beam charged particle beam system 1.

A third setting adjustment step S3 comprises selecting at least one region of interest 255 within an exposure area 251 of the plurality of primary charged particle beamlets 3. The at least one region of interest 255 can be selected and determined from prior information, for example from CAD-information or from previously acquired images of the inspection site. Generally, a region or interest 255 can be selected according to prior information. Prior information can be received or determined for example from CAD files of a wafer or previous inspection images, for example from optical inspection. Prior information can comprise registration information of a wafer, comprising the locations of the plurality of dies on the surface of the wafer.

In an example, the setting adjustment further comprises filter step F of a driving adjustment mechanism for filtering individual beamlets 3.1, 3.2, or 3.3 during image acquisition according to the selected region of interest 255. Examples of a possible mechanism are given by masking blades 351.1 to 351.4, deflectors 355 or multi-aperture lens array 306. Thereby, a beam current I.k of an individual beamlet 3.k is reduced. In an example, a beam current I.k of an individual beamlet 3.k is reduced to zero, with I.k=0, and at least one beamlet 3.k is blocked or filtered completely.

The method further comprises an image scanning step A. In an example, the image scanning step A is limited to a region of interest 255 comprised within a single die 711. Thereby, a charging at a border or edge 701 of a die 711 is reduced. In an example, the image scanning step A is limited to a scanning range at a border or edge of a wafer 7. Thereby, a charging at a border or edge of a wafer 7 is reduced.

The method further comprises an image data acquisition step I for receiving and storing image data acquired during the image scanning step A.

The method of operating a multi-beam charged particle beam system with reduced surface charging comprises a filter step F for blocking or filtering at least one beamlet 3.1, 3.2, 3.3 or 3.4 selected from a plurality of primary charged particle beamlets 3 according to regions on a surface 25 of a wafer 7 not required to be imaged during an inspection task.

According to the disclosure, a surface charge is reduced by filtering individual beamlets of the plurality of primary beamlets. Thereby, a deteriorating effect of a surface charge is reduced. The scanning image acquisition with the multi-beam charged particle beam system is performed with high resolution within at least one limited region of interest. By filtering individual beamlet which are scanning over areas outside the at least one limited region of interest, a charging of surface areas outside of the regions of interest (255) is reduced or completely eliminated.

A multi-beam charged particle beam system 1 according to the disclosure comprises a filtering mechanism such as masking blades 351, a deflector array 355, or a multi-aperture lens array 306, working in conjunction with a beam dump 357 or current limiting filter 308. The multi-beam charged particle beam system 1 further comprises a control unit 800 configured to adjust or drive a filtering mechanism during a scanning image acquisition.

A list of reference numbers is provided:
1 multi-beam charged-particle beam system
3 primary charged particle beamlets, or plurality of primary charged particle beamlets
5 primary charged particle beam spot or focus spot
7 object, for example wafer
9 secondary electron beamlet, forming the plurality of secondary electron beamlets
11 primary beam path
13 secondary electron beam path
15 secondary electron image spot
21 common pupil plane
25 surface of object
61 SE yield curve of first material composition
62 SE yield curve of second material composition
63 low energy transition point
65 high energy transition point
100 object irradiation unit
101 object plane
102 objective lens
103 field lens
108 beam cross over
110 first scanning deflector
112 electrostatic element
137 equipotential lines of extraction field
139 electrical field vector
141 interaction volume
143 Scanning direction
191 secondary electron trajectory
200 detection unit
205 electron-optical lens
214 aperture filter module
222 second deflector
225 detection or image plane
230 monitoring system
241 scanning line
243 fly-back
245 image patch of single beamlet
251 surface area segment captured by plurality of beamlets
253 surface area segment captured by plurality of beamlets, limited to region of interest
284 aperture filter
300 charged-particle multi-beamlet generator
301 charged particle source
303 collimating lenses
304 filter plate
305 multi-aperture arrangement
306 multi-aperture lens array
308 current limiting filter
309 primary electron beam
311 spacer
321 intermediate image surface
331 first field lens
333 second field lens
351 masking blade(s)
352 masking blade unit
353 rotation vector
354 masking blade driving device
355 deflector array
357 beam dump
359 deflection angle
400 beam divider
500 sample stage
503 Sample voltage supply
600 image sensor or detector
701 border or edge of a die
711 die
800 control unit
810 imaging control module
820 monitoring control unit
830 primary beampath control module
840 secondary beampath control module
850 stage control module
860 scanning operation control unit
880 Control operation processor
890 memory
2105 optical axis of detection unit

1. A method, comprising:
adjusting an inspection site of a surface of a wafer in an image plane of an object irradiation unit of a multi-beam charged particle beam system;
selecting a region of interest within an exposure area of the multi-beam charged particle beam system;
adjusting an inspection setting by a method comprising driving an adjustment mechanism to filter an individual beamlet according to regions on a surface of the wafer outside of the region of interest; and
image scanning the region of interest on the surface of the wafer to inspect the wafer.

2. The method of claim 1, wherein the driving of the adjustment mechanism comprises driving at least one member selected from the group consisting of a masking blade, a deflector array, and a multiaperture lens array.

3. The method of claim 1, wherein the region of interest comprises at least one member selected from the group consisting of a single die, a border or edge of a die, and a border or edge of a wafer.

4. The method of claim 1, wherein the region of interest is selected from CAD data of the wafer at the inspection site.

5. The method of claim 1, wherein the region of interest is selected to reduce surface charging outside the region of interest.

6. One or more machine-readable hardware storage devices comprising instructions that are executable by one or more processing devices to perform the method of claim 1.

7. A system, comprising:
one or more processing devices; and
one or more machine-readable hardware storage devices comprising instructions that are executable by one or more processing devices to perform the method of claim 1.

8. The system of claim 7, further comprising:
an object irradiation unit configured to provide a plurality of focus spots of a plurality of primary charged particle beamlets in an image plane of the multi-beam charged particle beam system, the object irradiation unit comprising:
a charged-particle multi-beamlet generator configured to generate the plurality of primary charged particle beamlets; and
a filtering mechanism configured to filter at least one primary charged particle beamlet; and
a detection unit configured to collect and image a plurality of secondary electron beamlets generated at the sample surface during exposure by the plurality of primary charge particle beamlets onto an image detector.

9. A multi-beam charged particle beam system, comprising:
an object irradiation unit configured to provide a plurality of focus spots of a plurality of primary charged particle beamlets in an image plane of the multi-beam charged particle beam system, the object irradiation unit comprising:
a charged-particle multi-beamlet generator configured to generate the plurality of primary charged particle beamlets; and
a filtering mechanism configured to filter at least one primary charged particle beamlet;
a detection unit configured to collect and image a plurality of secondary electron beamlets generated at the sample surface during exposure by the plurality of primary charge particle beamlets onto an image detector; and
a control unit configured to control the filtering mechanism so that the filter mechanism filters the at least one primary charged particle beamlet according to a predetermined exposure area of the surface of the sample.

10. The system of claim 9, further comprising a sample stage configured to support a surface of a sample in the image plane.

11. The system of claim 9, wherein the filtering mechanism comprises a movable masking blade.

12. The system of claim 11, wherein the movable masking blade is proximal to an intermediate image surface of the object irradiation unit.

13. The system of claim 9, wherein the filtering mechanism comprises deflector array and a beam dump.

14. The system of claim 13, wherein the deflector array is proximal to an intermediate image surface of the object irradiation unit.

15. The system of claim 14, wherein the deflector array is within the charged-particle multi-beamlet generator.

16. The system of claim 13, wherein the deflector array is within the charged-particle multi-beamlet generator.

17. The system of claim 9, wherein the filtering mechanism comprises a lens array and an aperture stop array configured to adjust a beam current of the at least one primary charged particle beamlet.

18. The system of claim 9, wherein the controller is configured to receive and store CAD information of a wafer, and the controller is configured to determine a region of interest at an inspection site from the CAD information.

19. A method of inspecting a surface of a wafer located in an image plane of a multi-beam charged particle beam system, the surface of a wafer comprising a first region and a second region different from the first region, the multi-beam charged particle beam system configured to generate a plurality of charged particle beamlets, a first individual charged particle beamlet configured to impinge on the first region but not the second region, a second individual charged particle beamlet configured to impinge on the second region but not the first region, the method comprising:
based on the first and second regions, adjusting a filtering mechanism of the multi-beam charged particle beam system so that the first individual charged beamlet passes through the filtering mechanism and impinges on the first region and so that the filtering mechanism prevents the second individual beamlet from impinging on the second region; and
image scanning the first region without image scanning the second region.

20. The method of claim 19, wherein the driving of the adjustment mechanism comprises driving at least one member selected from the group consisting of a masking blade, a deflector array, and a multiaperture lens array.

21. (canceled)

22. (canceled)

23. (canceled)

24. (canceled)

25. (canceled)
